(19) United States
(12) Patent Application Publication
(10) Pub. No.: US 2014/0034911 A1
(43) Pub. Date: Feb. 6, 2014

(54) Organic Light-Emitting Diode

(71) Applicants: Yawei Liu, Shenzhen City (CN); Yuanchun Wu, Shenzhen City (CN)

(72) Inventors: Yawei Liu, Shenzhen City (CN); Yuanchun Wu, Shenzhen City (CN)

(73) Assignee: Shenzhen China Star Optoelectronics Technology Co. Ltd., Shenzhen City, Guangdong (CN)

(21) Appl. No.: 13/699,725

(22) PCT Filed: Aug. 16, 2012
(86) PCT No.: PCT/CN12/80200

§ 371 Date: Nov. 24, 2012

(30) Foreign Application Priority Data
Aug. 6, 2012 (CN) 201210277172.4

(51) Int. Cl. H01L 51/00

(52) U.S. Cl. CPC H01L 51/0078; H01L 51/0084
USPC 257/40

(57) ABSTRACT

The present invention relates to an organic light-emitting diode, which includes: a light-transmitting substrate, an anode formed on the light-transmitting substrate, a hole transport layer formed on the anode, a light-emitting layer formed on the hole transport layer, an electron transport layer formed on the light-emitting layer, and a cathode formed on the electron transport layer. The light-emitting layer includes a plurality of pixel units, each of which includes red, green, blue, and infrared sub-pixel points. The red, green, blue, and infrared sub-pixel points are driven by thin-film transistors. The organic light-emitting diode of the present invention combines color displaying and infrared displaying in a single component and realizes switchability between color displaying and infrared displaying in the same component. The organic light-emitting diode greatly reduces the manufacture cost, shows wide applicability, and facilitates popularization

### BACKGROUND OF THE INVENTION

1. Field of the Invention

The present invention relates to the field of flat panel display, and in particular to an organic light-emitting diode (OLED).

2. The Related Arts

Infrared waveband is an important electromagnetic wave band for military and civil applications and has a wavelength range of 0.78-1,000 μm. Infrared light is commonly used in heating, physiotherapy, night vision, communication, navigation, plant growing, and animal farming. Applications of infrared light that are commonly seen in regular living include high-temperature sterilization, infrared light night vision device, surveillance device, infrared port of mobile phone, card key of hotel room, remote controls of automobile and television set, infrared sensing for wash basin, and infrared sensing door. Further, window wavelengths of optic fiber communication, including 850 nm, 1,130 nm, and 1,550 nm, are all located in the infrared waveband. Further, the infrared waveband also relates to applications of data processing, storage, security marking, infrared survey, and infrared aiming.

Commonly used infrared generators include xenon lamps, heated objects, or laser devices, but they cannot effect infrared displaying. Inorganic semiconductor infrared generator is based on inorganic compound having a primary ingredient of tellurium, cadmium, and mercury. The drawback of the inorganic infrared semiconductor substance is that the manufacture cost is high, the operation is complicated, and is incapable of forming a thin film on a substrate of polycrystalline, amorphous, and flexible plastics. The drawback of the inorganic infrared semiconductor substance imposes a constraint to wide applications of infrared displays on military field.

The organic semiconductor material has various advantages over the inorganic infrared semiconductor material in respect of low cost and light weight, excellent dissolubility, being easy to make large-area flexible component, and being capable of modifying opto-electrical characteristics through molecular tailoring. An organic light-emitting component has various advantages, including wide selection of material, low driving voltage, high response speed, large view angle of light emission, light weight, being ultra thin, flexible substrate, large area, and being capable of manufacturing film through mass production.

An infrared organic light-emitting diode (OLED) display is made of an organic semiconductor material and provides a display image that is invisible to bare eyes and can only be viewed through night vision goggles. Combining the display with soldiers' uniform or equipment allow the soldiers to do communication without being noticed by enemies and also provides the capability of observation through fog and rain. Further, the organic light-emitting diode is also applicable to infrared survey devices.

Meanwhile, color organic light-emitting diodes are the next generation of displaying techniques because of the characteristics of active light emission, light weight, and reduced power consumption. Currently, small-sized panels are available for use in electronic devices, such as mobile phones and MP3. Referring to FIG. 1, an individual pixel unit 100 of an organic light-emitting layer of the organic light-emitting diode is made up of a red sub-pixel point 102, a green sub-pixel point 104, and a blue sub-pixel point 106 (RGB), which when used in combination with a thin-film transistor (TFT) array drive circuit can effect color displaying.

The research and development of the infrared organic light-emitting diode and the color organic light-emitting diode have important scientific meaning and a prosperous and wide application in the future. However, the technical persons of this field have not yet developed an organic light-emitting diode that features both infrared displaying and color displaying.

### SUMMARY OF THE INVENTION

An object of the present invention is to provide an organic light-emitting diode, which features both infrared displaying mode and color displaying mode and has a simple structure, making it easy to realize.

To achieve the object, the present invention provides an organic light-emitting diode, which comprises: a light-transmitting substrate, an anode formed on the light-transmitting substrate, a hole transport layer formed on the anode, a light-emitting layer formed on the hole transport layer, an electron transport layer formed on the light-emitting layer, and a cathode formed on the electron transport layer. The light-emitting layer comprises a plurality of pixel units, each of which comprises red, green, blue, and infrared sub-pixel points. The red, green, blue, and infrared sub-pixel points are driven by thin-film transistors.

The infrared sub-pixel point is made of an infrared light-emitting material.

The infrared light-emitting material comprises copper phthalocyanine or tris(8-hydroxyquinolinato)erbium.

The red, green, blue, and infrared sub-pixel points of each of the pixel units are arranged in a juxtaposed manner.

The red sub-pixel point, the green sub-pixel point, the blue sub-pixel point, and the infrared sub-pixel point of each of the pixel units are juxtaposed sequentially from left to right.

The red, green, blue, and infrared sub-pixel points of each of the pixel units are arranged in a square array.

The arrangement is made in such a way that, starting from a left upper corner, the red sub-pixel point, the green sub-pixel point, the infrared sub-pixel point, and the blue sub-pixel point of each of the pixel units are clockwise set in such a sequence.

The light-transmitting substrate comprises a glass substrate.

The anode comprises indium tin oxides.

The anode is formed on the light-transmitting substrate through sputtering.

The present invention also provides an organic light-emitting diode, comprising: a light-transmitting substrate, an anode formed on the light-transmitting substrate, a hole transport layer formed on the anode, a light-emitting layer formed on the hole transport layer, an electron transport layer formed on the light-emitting layer, and a cathode formed on the electron transport layer, the light-emitting layer comprising a plurality of pixel units, each of which comprises red, green, blue, and infrared sub-pixel points, the red, green, blue, and infrared sub-pixel points being driven by thin-film transistors;

wherein the infrared sub-pixel point is made of an infrared light-emitting material;

wherein the infrared light-emitting material comprises copper phthalocyanine or tris(8-hydroxyquinolinato)erbium;

wherein the red, green, blue, and infrared sub-pixel points of each of the pixel units are arranged in a juxtaposed manner;

wherein the red sub-pixel point, the green sub-pixel point, the blue sub-pixel point, and the infrared sub-pixel point of each of the pixel units are juxtaposed sequentially from left to right;

wherein the light-transmitting substrate comprises a glass substrate;

wherein the anode comprises indium tin oxides; and

wherein the anode is formed on the light-transmitting substrate through sputtering.

The efficacy of the present invention is that the present invention provides an organic light-emitting diode that combines color displaying and infrared displaying in a single component and realizes switchability between color displaying and infrared displaying in the same component. The organic light-emitting diode that has an infrared displaying function overcomes the drawbacks of an inorganic semiconductor infrared component that the manufacture cost is high, the manufacture is complicated, being incapable of forming a thin film on a polycrystalline, amorphous, or flexible plastic substrate so as to greatly reduce the manufacture cost, shows wide applicability, and facilitates popularization.

For better understanding of the features and technical contents of the present invention, reference will be made to the following detailed description of the present invention and the attached drawings. However, the drawings are provided for the purposes of reference and illustration and are not intended to impose undue limitations to the present invention.

### BRIEF DESCRIPTION OF THE DRAWINGS

The technical solution, as well as beneficial advantages, of the present invention will be apparent from the following detailed description of an embodiment of the present invention, with reference to the attached drawings. In the drawings:

FIG. 1 is a schematic view illustrating the arrangement of pixel unit of a conventional color organic light-emitting diode;

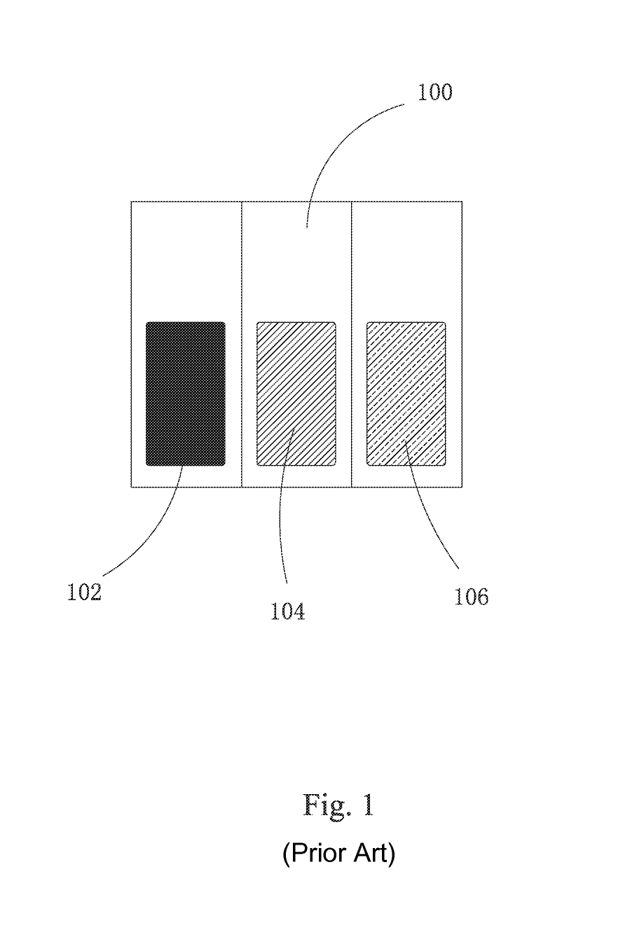

FIG. 2 is a schematic view showing the structure of pixel unit of organic light-emitting diode according to an embodiment of the present invention;

FIG. 3 is a schematic view showing a TFT drive circuit of the pixel unit of FIG. 2;

FIG. 4 is a plot showing peak of emission spectrum for an infrared light-emitting material containing copper phthalocyanine;

FIG. 5 is a plot showing peak of emission spectrum for an infrared light-emitting material containing tris(8-hydroxyquinolinato)erbium;

FIG. 6 is a schematic view showing the structure of pixel unit of organic light-emitting diode according to anther embodiment of the present invention; and

FIG. 7 is a schematic view showing a TFT drive circuit of the pixel unit of FIG. 6.

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

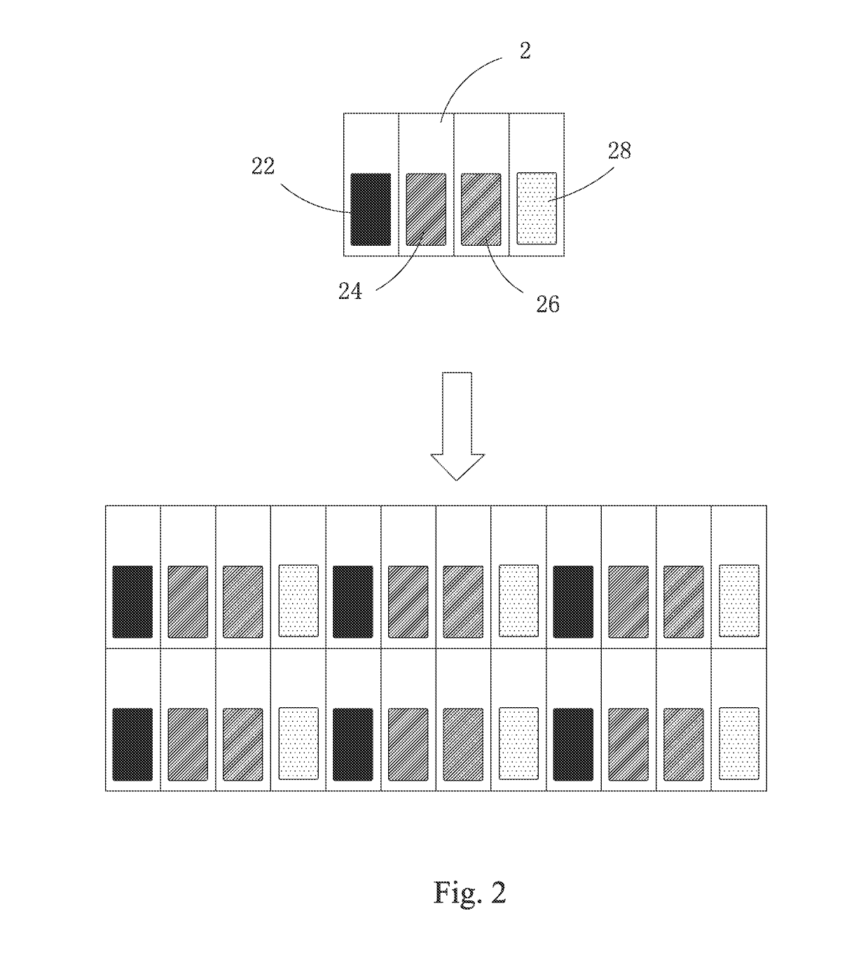

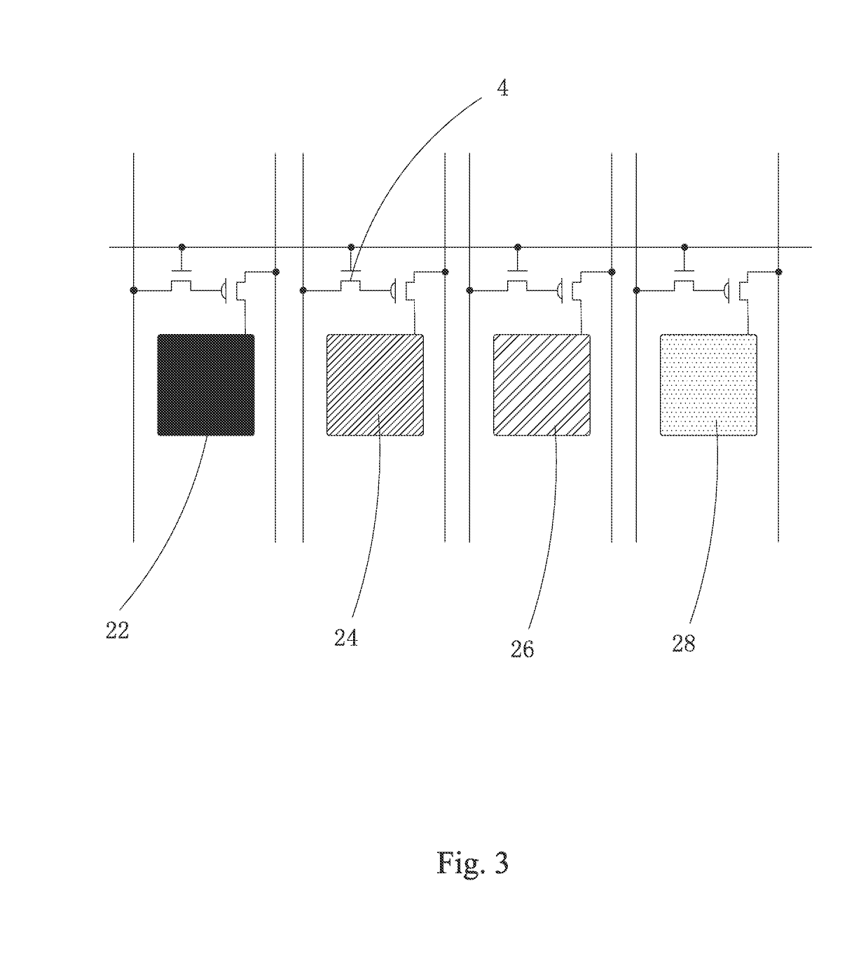

Referring to FIGS. 2 and 3, the present invention provides an organic light-emitting diode (OLED), which comprises: a light-transmitting substrate, an anode formed on the light-transmitting substrate, a hole transport layer formed on the anode, a light-emitting layer formed on the hole transport layer, an electron transport layer formed on the light-emitting layer, and a cathode formed on the electron transport layer (all being not shown).

The light-emitting layer comprises a plurality of pixel units 2. Each pixel unit 2 comprises red, green, blue, and infrared sub-pixel points 22, 24, 26, 28. The red, green, blue, and infrared sub-pixel points 22, 24, 26, 28 are all driven by thin-film transistors 4. In the instant embodiment, the red, green, blue, and infrared sub-pixel points 22, 24, 26, 28 of each pixel unit 2 are set in a juxtaposed arrangement. Preferably, the juxtaposition is to sequentially arrange the red sub-pixel point 22, the green sub-pixel point 24, the blue sub-pixel point 26, and the infrared sub-pixel point 28 from left to right.

When the thin-film transistors 4 drive the red, green, and blue sub-pixel points 22, 24, 26, the organic light-emitting diode according to the present invention provides a displaying mode that is color mode and when the thin-film transistor 4 drives the infrared sub-pixel point 28, the organic light-emitting diode of the present invention provides a displaying mode that is infrared mode, whereby an organic light-emitting diode having two different displaying modes can be realized, allowing the organic light-emitting diode to be applicable to a wide range.

In the instant embodiment, the light-transmitting substrate is a glass substrate. The anode comprises indium tin oxides (ITO) that is formed on the light-transmitting substrate through sputtering. The hole transport layer comprises a layer of N,N′-di(3-methylphenyl)-N,N′-biphenyl-1,1′-biphenyl-4,4′-diamine (TPD) or a layer of N,N′-di(1-naphthyl)-N,N′-biphenyl-1,1′-biphenyl-4,4′-diamine (NPD). A hole blocking layer comprises a layer of 1,3,5-(benzenetriyl)tris(1-phenyl-1H-benzimidazole) (TPBI) or a layer of 2,9-dimethyl-4,7-diphenyl-1,10-phenanthroline (BCP). The electron transport layer comprises a layer of doped 8-hydroxyquinoline aluminum (Alq₃). The cathode comprises aluminum (Al) or silver (Ag).

The infrared sub-pixel point 28 is made up of an infrared light-emitting material. The infrared light material can be an organic metal compound, such as copper phthalocyanine or tris(8-hydroxyquinolinato)erbium.

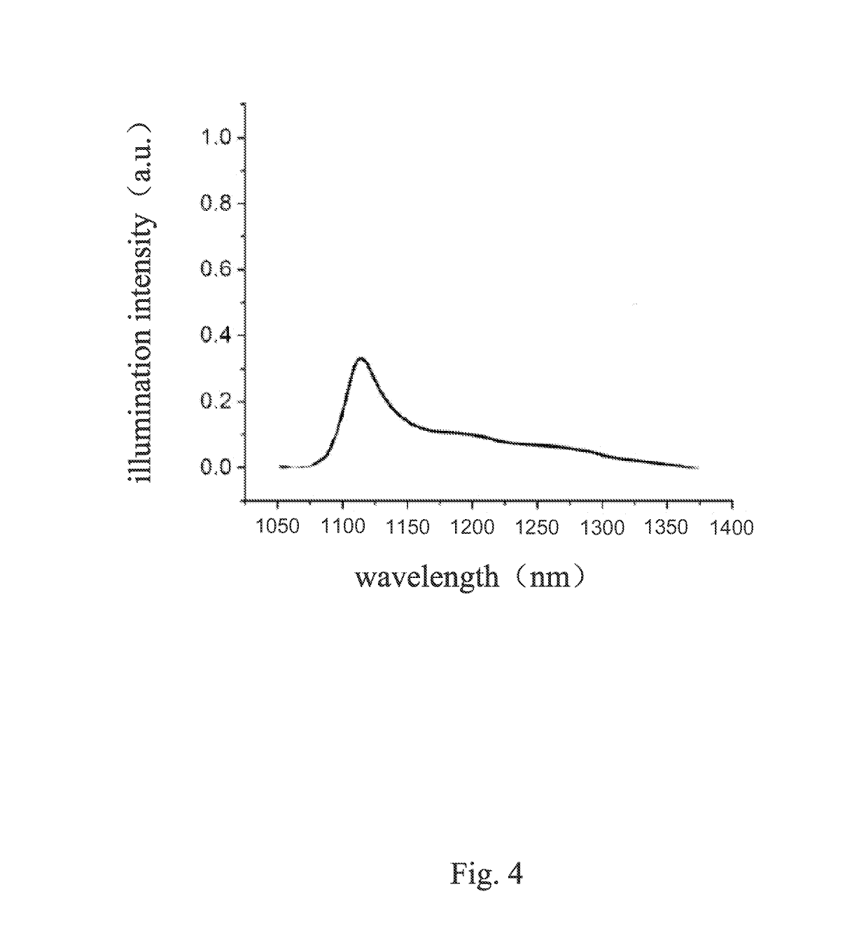

Referring to FIG. 4, which is a plot showing peak of emission spectrum for an infrared light-emitting material containing copper phthalocyanine, it is noted that the peak of the emission spectrum is at 1,120 nm, which belongs to the infrared waveband. The copper phthalocyanine material has the following formula:

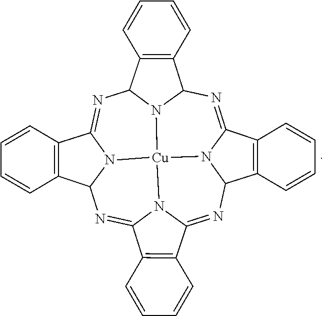

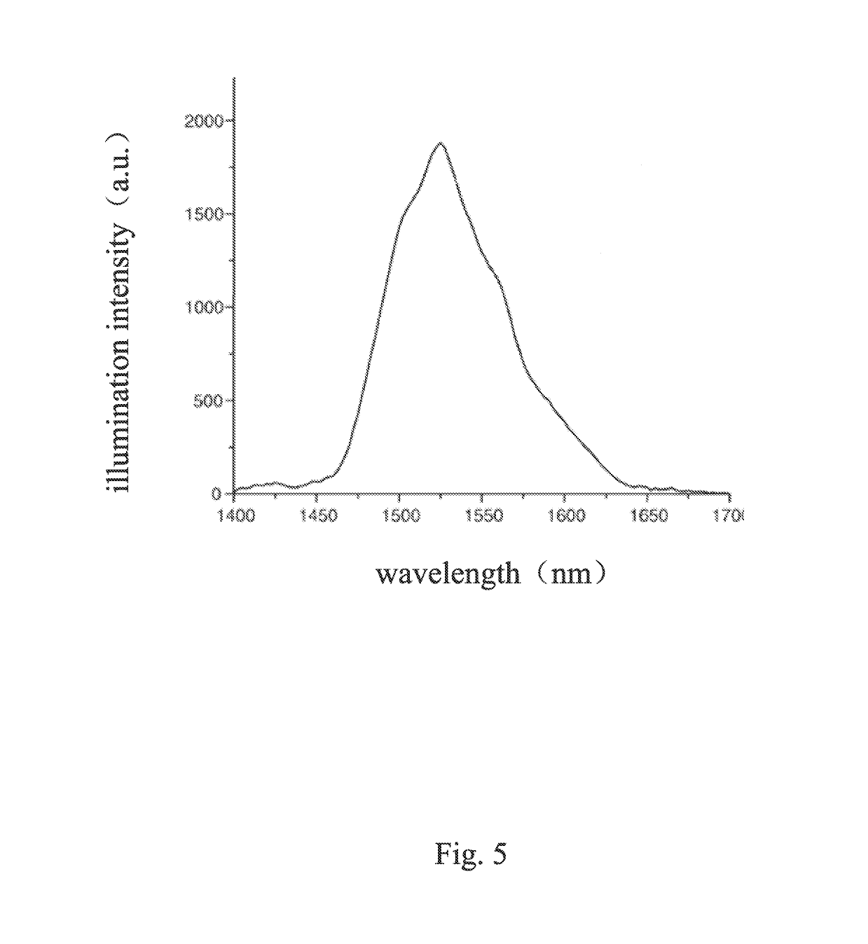

Referring to FIG. 5, which is a plot showing peak of emission spectrum for an infrared light-emitting material containing tris(8-hydroxyquinolinato)erbium, it is noted that the peak of the emission spectrum is at 1,530 nm, which belongs to the infrared waveband. The tris(8-hydroxyquinolinato)erbium material has the following formula:

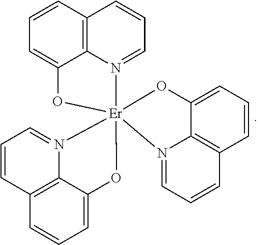

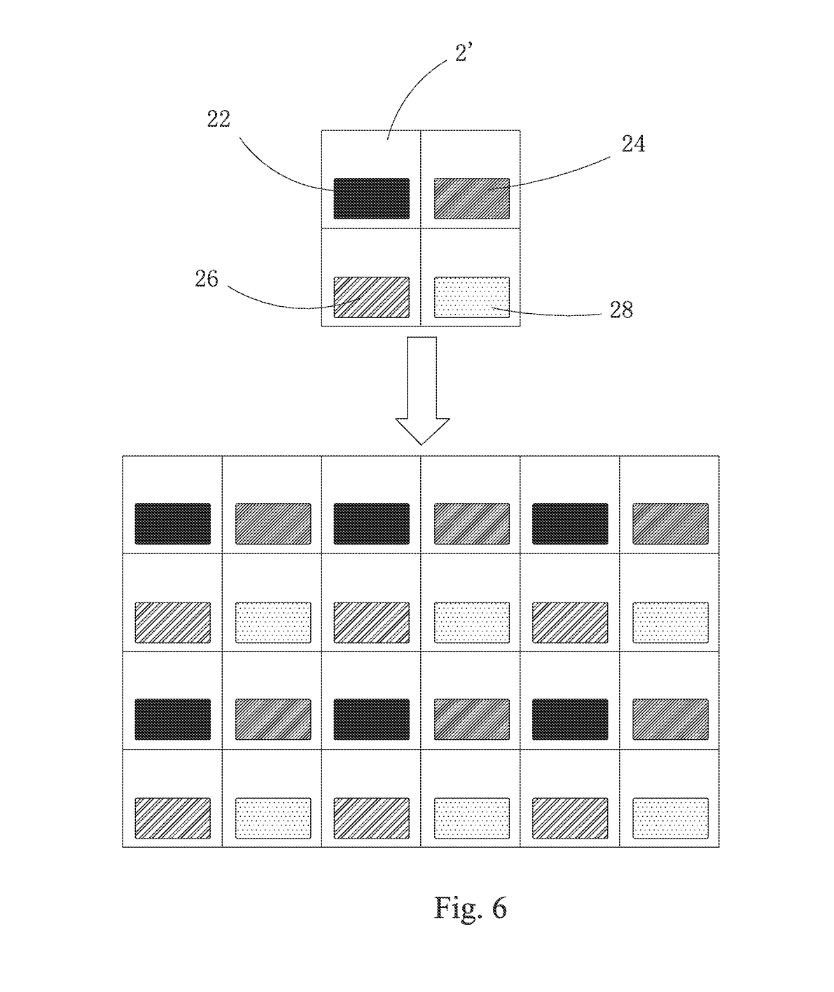

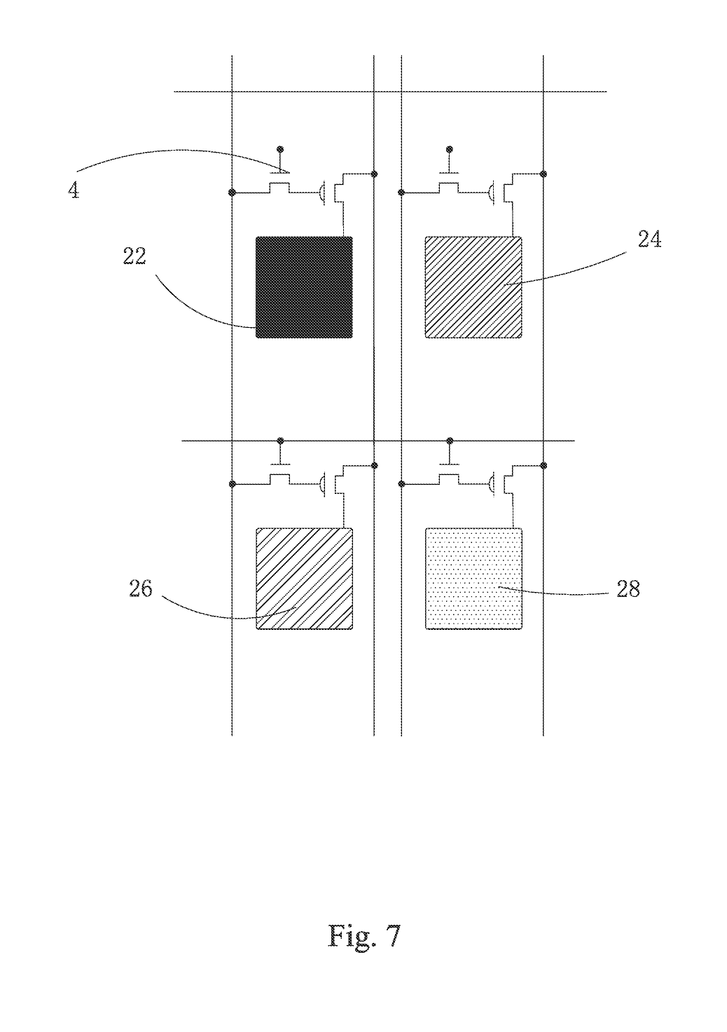

Referring to FIGS. 6 and 7, which are schematic views showing the structure of pixel unit of organic light-emitting diode according to anther embodiment of the present invention, in the instant embodiment, the red, green, blue, and infrared sub-pixel points 22, 24, 26, 28 of a pixel unit 2′ are arranged in a square array. Preferably, the arrangement is made in such a way that, starting from the left upper corner, the red sub-pixel point 22, the green sub-pixel point 24, the infrared sub-pixel point 28, and the blue sub-pixel point 26 are sequentially and clockwise set.

The organic light-emitting diode according to the present invention is applicable to a mobile phone with the OLED screen normally acting as a color display screen and being switchable to an infrared mode when needed for opening a room door or an automobile door, or serving as a remote control of television set. It can be further applied to a display device carried by an individual soldier to provide a color display mode in the daytime and to display an infrared image in the nighttime by being used in combination with an infrared survey device. It also allows a soldier to do infrared communication in the nighttime without being noticed by enemies.

In summary, the present invention provides an organic light-emitting diode that combines color displaying and infrared displaying in a single component and realizes switchability between color displaying and infrared displaying in the same component. The organic light-emitting diode that has an infrared displaying function overcomes the drawbacks of an inorganic semiconductor infrared component that the manufacture cost is high, the manufacture is complicated, being incapable of forming a thin film on a polycrystalline, amorphous, or flexible plastic substrate so as to greatly reduce the manufacture cost, shows wide applicability, and facilitates popularization.

Based on the description given above, those having ordinary skills in the art may easily contemplate various changes and modifications of the technical solution and technical ideas of the present invention and all these changes and modifications are considered within the protection scope of right for the present invention.

What is claimed is:

1. An organic light-emitting diode, comprising: a light-transmitting substrate, an anode formed on the light-transmitting substrate, a hole transport layer formed on the anode, a light-emitting layer formed on the hole transport layer, an electron transport layer formed on the light-emitting layer, and a cathode formed on the electron transport layer, the light-emitting layer comprising a plurality of pixel units, each of which comprises red, green, blue, and infrared sub-pixel points, the red, green, blue, and infrared sub-pixel points being driven by thin-film transistors.

2. The organic light-emitting diode as claimed in claim 1, wherein the infrared sub-pixel point is made of an infrared light-emitting material.

3. The organic light-emitting diode as claimed in claim 2, wherein the infrared light-emitting material comprises copper phthalocyanine or tris(8-hydroxyquinolinato)erbium.

4. The organic light-emitting diode as claimed in claim 1, wherein the red, green, blue, and infrared sub-pixel points of each of the pixel units are arranged in a juxtaposed manner.

5. The organic light-emitting diode as claimed in claim 4, wherein the red sub-pixel point, the green sub-pixel point, the blue sub-pixel point, and the infrared sub-pixel point of each of the pixel units are juxtaposed sequentially from left to right.

6. The organic light-emitting diode as claimed in claim 1, wherein the red, green, blue, and infrared sub-pixel points of each of the pixel units are arranged in a square array.

7. The organic light-emitting diode as claimed in claim 6, wherein the arrangement is made in such a way that, starting from a left upper corner, the red sub-pixel point, the green sub-pixel point, the infrared sub-pixel point, and the blue sub-pixel point of each of the pixel units are clockwise set in such a sequence.

8. The organic light-emitting diode as claimed in claim 1, wherein the light-transmitting substrate comprises a glass substrate.

9. The organic light-emitting diode as claimed in claim 1, wherein the anode comprises indium tin oxides.

10. The organic light-emitting diode as claimed in claim 9, wherein the anode is formed on the light-transmitting substrate through sputtering.

11. An organic light-emitting diode, comprising: a light-transmitting substrate, an anode formed on the light-transmitting substrate, a hole transport layer formed on the anode, a light-emitting layer formed on the hole transport layer, an electron transport layer formed on the light-emitting layer, and a cathode formed on the electron transport layer, the light-emitting layer comprising a plurality of pixel units, each of which comprises red, green, blue, and infrared sub-pixel points, the red, green, blue, and infrared sub-pixel points being driven by thin-film transistors;
wherein the infrared sub-pixel point is made of an infrared light-emitting material;
wherein the infrared light-emitting material comprises copper phthalocyanine or tris(8-hydroxyquinolinato)erbium;
wherein the red, green, blue, and infrared sub-pixel points of each of the pixel units are arranged in a juxtaposed manner;
wherein the red sub-pixel point, the green sub-pixel point, the blue sub-pixel point, and the infrared sub-pixel point of each of the pixel units are juxtaposed sequentially from left to right;
wherein the light-transmitting substrate comprises a glass substrate;
wherein the anode comprises indium tin oxides; and
wherein the anode is formed on the light-transmitting substrate through sputtering.
